(19) United States
(12) Patent Application Publication
(10) Pub. No.: US 2016/0329481 A1
(43) Pub. Date: Nov. 10, 2016

(54) BULK ACOUSTIC WAVE RESONATOR AND FILTER INCLUDING THE SAME

(71) Applicant: SAMSUNG ELECTRO-MECHANICS CO., LTD., Suwon-si (KR)

(72) Inventors: Tae Yoon KIM, Suwon-si (KR); Yeong Gyu LEE, Suwon-si (KR); Moon Chul LEE, Suwon-si (KR); Jae Chang LEE, Suwon-si (KR); Duck Hwan KIM, Suwon-si (KR)

(73) Assignee: SAMSUNG ELECTRO-MECHANICS CO., LTD., Suwon-si (KR)

(21) Appl. No.: 14/991,110

(22) Filed: Jan. 8, 2016

(30) Foreign Application Priority Data
May 4, 2015 (KR) 10-2015-0062573
Jun. 10, 2015 (KR) 10-2015-0082072

(51) Int. Cl. H03H 9/54; H01L 41/047

(52) U.S. Cl. CPC H01L 41/047; H03H 9/54

(57) ABSTRACT

A bulk acoustic wave resonator includes a resonating part comprising a first electrode, a piezoelectric layer, and a second electrode sequentially laminated, wherein the resonating part is disposed on a substrate; and a cap comprising a groove part configured to accommodate the resonating part, a frame bonded to the substrate by a bonding agent, and a permeation preventing part configured to block the bonding agent from permeating into the groove part from the frame.

### CROSS-REFERENCE TO RELATED APPLICATIONS

This application claims the benefits of Korean Patent Application Nos. 10-2015-0062573 and 10-2015-0082072 filed on May 4, 2015 and Jun. 10, 2015, respectively, in the Korean Intellectual Property Office, the entire disclosures of which are incorporated herein by reference for all purposes.

### BACKGROUND

1. Field

The following description relates to a bulk acoustic wave resonator and a filter including the same.

2. Description of Related Art

In accordance with a rapid increase in development of mobile communications devices, chemical devices, and biological devices the demand for compact and lightweight filters, oscillators, resonant elements, acoustic resonant mass sensors, and other elements has also increased. Film bulk acoustic resonators (hereinafter referred to as “FBAR”) have been used a means for implementing the compact and lightweight filters, oscillators, resonant elements, and acoustic resonant mass sensors. The FBAR has an advantage in that it may be mass produced at a minimal cost and may be subminiaturized. Further, the FBAR has advantages in that it allows a high quality factor Q value, which is a main property of a filter. Further, the FBAR may even be used in a micro-frequency band, and operate at bands of a personal communications system (PCS) and a digital cordless system (DCS). Generally, the FBAR has a structure including a resonating part formed by sequentially laminating a first electrode, a piezoelectric layer, and a second electrode on a substrate.

An operation principle of the FBAR will be described below. First, when an electric field is induced in the piezoelectric layer by applying electric energy to the first and second electrodes, the electric field causes a piezoelectric phenomenon of the piezoelectric layer, thereby causing the resonating part to vibrate in a predetermined direction. As a result, a bulk acoustic wave is generated in the same direction as the vibration direction of the resonating part, thereby causing resonance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic wave resonator is capable of securing reliability by preventing a bonding agent from being permeated into the interior of the bulk acoustic wave resonator, and a filter includes the same. The bulk acoustic wave resonator includes a resonating part comprising a first electrode, a piezoelectric layer, and a second electrode sequentially laminated, wherein the resonating part is disposed on a substrate; and a cap having a groove part configured to accommodate the resonating part, a frame bonded to the substrate by a bonding agent, and a permeation preventing part configured to block the bonding agent from permeating into the groove part from the frame.

In another general aspect, a filter includes bulk acoustic wave resonators, wherein each of the bulk acoustic wave resonators includes a resonating part having a first electrode, a piezoelectric layer, and a second electrode sequentially laminated, wherein the each of resonating parts is disposed on a substrate; and a cap having a groove part configured to accommodate the resonating part, a frame bonded to the substrate by a bonding agent, and a permeation preventing part configured to block the bonding agent from permeating into the groove part from the frame.

Other features and aspects will be apparent from the following detailed description, the drawings, and the claims.

### BRIEF DESCRIPTION OF DRAWINGS

FIG. 1 is a cross-sectional view illustrating an example of a bulk acoustic wave resonator;

FIG. 2A is a top view of the bulk acoustic wave resonator at a wafer level;

FIG. 2B is a partially enlarged view of a portion illustrated by a dotted line of FIG. 2A;

FIG. 2C is a view illustrating an example of an actual bulk acoustic wave resonator in which a bonding agent is permeated in FIG. 2B;

FIG. 3A is a cross-sectional view taken along line I-I′ of FIG. 2B and 2C before bonding;

FIG. 3B is a cross-sectional view taken along line I-I′ of FIGS. 2B and 2C after bonding;

FIG. 4A is a partial top view of an example of a cap;

FIG. 4B is a cross-sectional view taken along line II-II' of FIG. 4A;

FIG. 5 is a partial top view of another example of a cap; and

FIGS. 6 and 7 are examples of schematic circuit diagrams of a filter.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

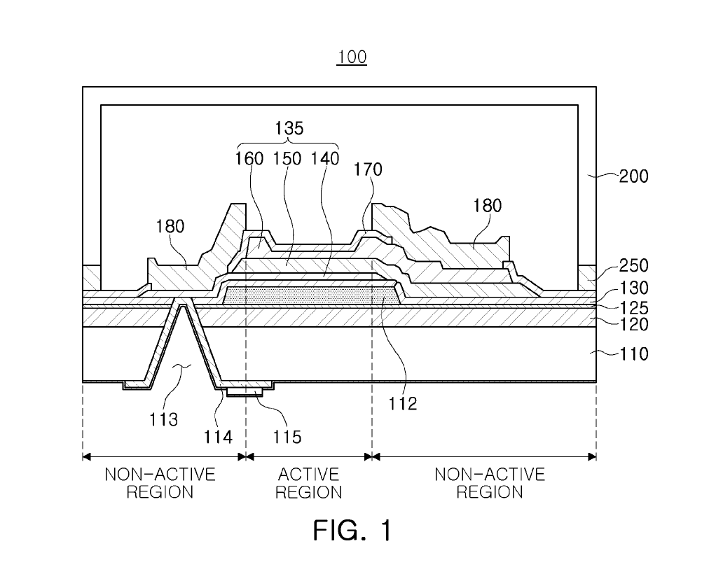

Referring to FIG. 1, a bulk acoustic wave resonator 100 is a film bulk acoustic resonator (hereinafter referred to as “FBAR”) and includes a substrate 110, an insulating layer 120, an air cavity 112, and a resonating part 135.

The substrate 110 may be formed of a typical silicon substrate, and the insulating layer 120 that electrically insulates the resonating part 135 from the substrate 110 is disposed on an upper surface of the substrate 110. The insulating layer 120 is formed by depositing silicon dioxide (SiO₂) or aluminum oxide (Al₂O₃) on the substrate 110 by a chemical vapor deposition, an RF magnetron sputtering method, or an evaporation method.

At least one via hole 113 penetrating through the substrate 110 is formed in a lower surface of the substrate 110. A connection conductor 114 surrounds the via hole 113. The connection conductor 114 is disposed on an inner surface of the via hole 113, that is, an overall inner wall of the via hole 113, but is not limited thereto. The connection conductor 114 comprises a conductive layer and is disposed on the inner surface of the via hole 113. For example, the connection conductor 114 may be formed by depositing, coating, or filling a conductive metal such as gold or copper along the inner wall of the via hole 113.

One end of the connection conductor 114 extends toward the lower surface of the substrate 110, and an external electrode 115 is disposed on the connection conductor 114 on the lower surface of the substrate 110. The other end of the connection conductor 114 is connected to a first electrode 140. Here, the connection conductor 114 is electrically connected to the first electrode 140 by extending through the substrate 110 and a membrane layer 130. Thereby, the connection conductor 114 electrically connects the first electrode 140 to the external electrode 115.

FIG. 1 illustrates only one via hole 113, one connection conductor 114, and one external electrode 115, but the number of via holes 113, connection conductors 114, and external electrodes 115 is not limited to one. The number of via holes 113, connection conductors 114, and external electrodes 115 may be varied as necessary. For example, the via hole 113, the connection conductor 114, and the external electrode 115 may also be formed in the second electrode 160 on another other side of the air cavity 112.

The air cavity 112 is disposed over the insulating layer 120. The air cavity 112 is disposed below the resonating part 135 so that the resonating part 135 vibrates in a predetermined direction. The air cavity 112 may be formed by disposing an air cavity sacrifice layer pattern on the insulating layer 120, then disposing a membrane 130 on the air cavity sacrifice layer pattern, and etching and removing the air cavity sacrifice layer pattern. An etching stop layer 125 is disposed between the insulating layer 120 and the air cavity 112. The etching stop layer 125 serves to protect the substrate 110 and the insulating layer 120 from an etching process and may serve as a base necessary to deposit other various layers on the etching stop layer 125.

The air cavity 112 may be formed by forming an air cavity sacrifice layer pattern on the insulating layer 120, then forming a membrane 130 on the air cavity sacrifice layer pattern, and etching and removing the air cavity sacrifice layer pattern. The membrane 130 may serve as an oxidation protection layer or serve as a protection layer protecting the substrate 110, or both.

The resonating part 135 includes a first electrode 140, a piezoelectric layer 150, and a second electrode 160 which are sequentially laminated to be disposed over the air cavity 112. The first electrode 140 is formed on an upper surface of the membrane 130 to cover a portion of the membrane 130. The first electrode 140 is formed of a typical conductive material such as a metal. Specifically, the first electrode 140 may be formed of gold (Au), titanium (Ti), tantalum (Ta), molybdenum (Mo), ruthenium (Ru), platinum (Pt), tungsten (W), aluminum (Al), nickel (Ni), or any combination thereof.

The piezoelectric layer 150 is formed on an upper surface of the membrane 130 and the first electrode 140 to cover a portion of the membrane 130 and a portion of the first electrode 140. The piezoelectric layer 150 generates a piezoelectric effect by converting electric energy into mechanical energy of an acoustic wave type. The piezoelectric layer 150 may be formed of aluminum nitride (AlN), zinc oxide (ZnO), lead zirconium titanium oxide (PZT; PbZrTiO), or any combination thereof.

The second electrode 160 is formed on the piezoelectric layer 150. Similarly to the first electrode 140, the second electrode 160 may be formed of a conductive material such as gold (Au), titanium (Ti), tantalum (Ta), molybdenum (Mo), ruthenium (Ru), platinum (Pt), tungsten (W), aluminum (Al), nickel (Ni), or any combination thereof.

The resonating part 135 comprises an active region and a non-active regions. The active region of the resonating part 135 vibrates in a predetermined direction by a piezoelectric effect when electrical energy, such as radio frequency (RF) signals, is applied to the first and second electrodes 140 and 160. The electrical energy induces an electric field in the piezoelectric layer 150. The active region of the resonating part 135 correspond to a region in which the first electrode 140, the piezoelectric layer 150, and the second electrode 160 overlap each other in a vertical direction over the air cavity 112. The non-active regions of the resonating part 135 are regions which are not resonated by the piezoelectric effect even though the electric energy is applied to the first and second electrodes 140 and 160. The non-active regions correspond to regions in which the first electrode 140, the piezoelectric layer 150, and the second electrode 160 do not overlap.

The resonating part 135 having the configuration as described above filters an RF signal of a specific frequency using the piezoelectric effect of the piezoelectric layer 150 as described above. That is, the RF signal applied to the second electrode 160 is output in a direction of the first electrode 140 through the resonating part 135. In this case, since the resonating part 135 has a constant resonance frequency according to the vibration occurring in the piezoelectric layer 150, the resonating part 135 outputs only a signal matched to the resonance frequency of the resonating part 135 among the applied RF signals.

A protection layer 170 is disposed on the second electrode 160 of the resonating part 135 to prevent the second electrode 160 from being externally exposed. The protection layer 170 is an insulating material. Here, the insulating material may include a silicon oxide based material, a silicon nitride based material, or an aluminum nitride based material, or any combination thereof.

Connection electrodes 180 disposed over the first electrode 140 and the second electrode 160 on the non-active regions, and extends through the protection layer 170 to be bonded to the first electrode 140 and the second electrode 160. The connection electrodes 180 confirm filter characteristics of the resonator and perform a required frequency trimming. However, the functions of the connection electrodes 180 are not limited thereto.

A cap 200 is bonded to the substrate 110 to protect the resonating part 135 from an external environment. The cap 200 includes an internal space in which the resonating part 135 is accommodated. Specifically, the cap 200 has a groove part, or base portion, formed at a center thereof to accommodate the resonating part 135, and a frame of the cap 200 extend perpendicularly from the groove part so as to be coupled to the resonator at an edge thereof. The frame may be directly or indirectly bonded to the substrate 110 through a bonding agent 250 at a specific region. Although FIG. 1 illustrates an embodiment in which the frame is bonded to the protection layer 170 laminated on the substrate 110, the frame may be bonded to the membrane 130, the etching stop layer 125, the insulating layer 120, or the substrate 110, or any combination thereof, by penetrating through the protection layer 170.

The cap 200 may be formed by a wafer bonding at a wafer level. That is, a substrate wafer on which a plurality of unit substrates 110 are disposed, and a cap wafer on which a plurality of caps 200 are disposed are bonded to each other to be integrally formed. The substrate wafer and the cap wafer which are bonded to each other may be cut by a cutting process later to be divided into a plurality of individual bulk acoustic wave resonators illustrated in FIG. 1.

The cap 200 may be bonded to the substrate 110 by a eutectic bonding. In this case, after the bonding agent 250, which may be eutectic-bonded to the substrate 110, is deposited on the substrate 110, the substrate wafer and the cap wafer are pressurized and heated to complete the eutectic-bonding process. The bonding agent 250 may include a eutectic material such as copper (Cu)—tin (Sn), and may also include a solder ball. However, when the substrate wafer and the cap wafer are bonded to each other, the bonding agent 250 may permeate into the interior of the resonator due to bonding pressure, thereby deteriorating reliability.

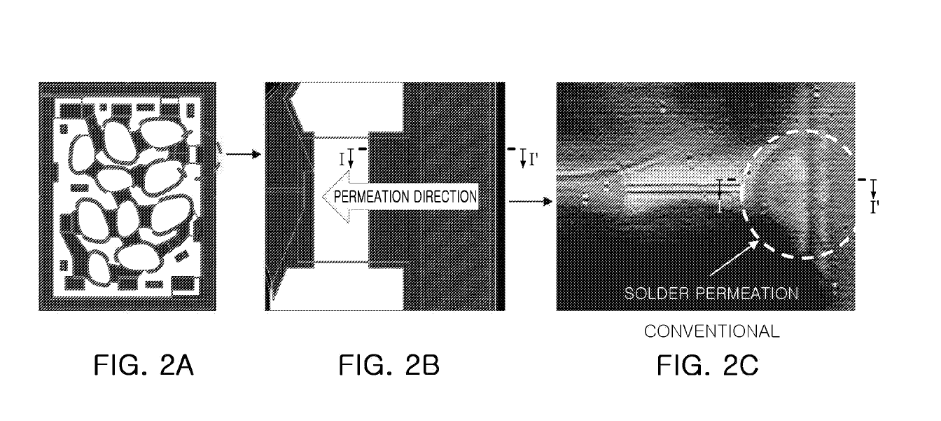

The bulk acoustic wave resonator on the wafer level of FIG. 2A is integrally formed by bonding a substrate wafer, on which a plurality of unit substrates 110 of FIG. 1 are disposed, to a cap wafer, on which a plurality of caps 200 are disposed to each other. The portion illustrated by the dotted line in FIG. 2A corresponds to a region of the bulk acoustic wave resonator 100 and the cap 200 of FIG. 1 that are bonded to each other by the bonding agent 250. As illustrated in FIG. 2B, the bonding agent permeates into the interior of the bulk acoustic wave resonator as illustrated by an arrow, thereby deteriorating reliability of the conventional bulk acoustic wave resonator at the wafer level as illustrated in FIG. 2C.

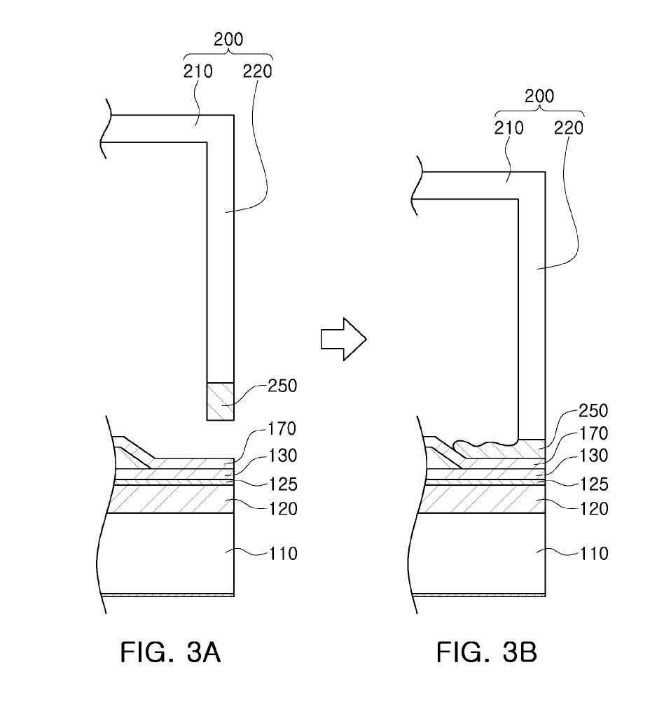

The cross-sectional views of FIGS. 3A and 3B are enlarged views of a portion of the bulk acoustic wave resonator of FIG. 1. Components illustrated in FIGS. 3A and 3B correspond to the components illustrated in FIG. 1.

FIG. 3A corresponds to a view illustrating the substrate 110 and the cap 200 before they are bonded to each other, and FIG. 3B is a view illustrating the substrate 110 and the cap 200 after they are bonded to each other.

Referring to FIG. 3A, before the substrate 110 of the bulk acoustic wave resonator and the cap 200 are bonded to each other, the bonding agent 250 is disposed on the frame 220 of the substrate 110. However, referring to FIG. 3B, when the substrate 110 of the bulk acoustic wave resonator and the cap 200 are bonded to each other, a problem may occur in which the bonding agent 250 permeates into the interior of the bulk acoustic wave resonator, particularly, into the active region of the resonating part 135 along the protection layer 170 due to the bonding pressure.

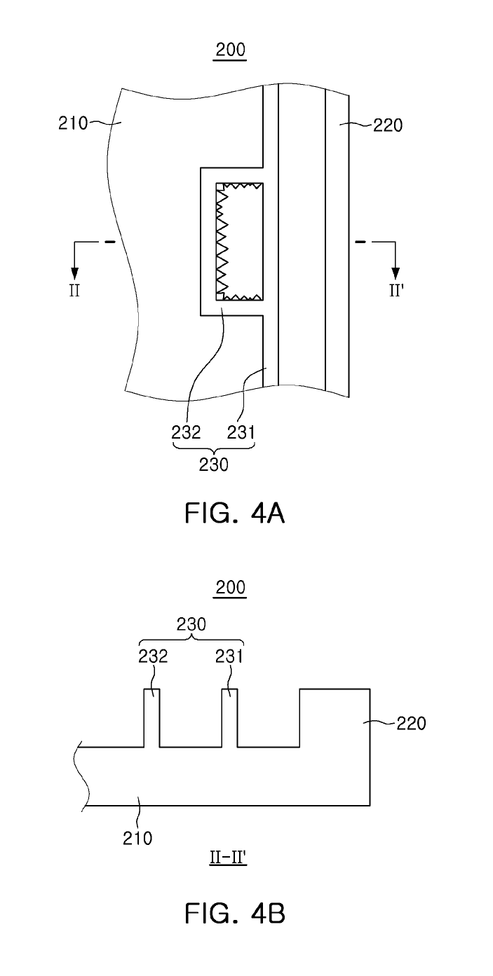

Referring to FIG. 4A, the cap 200 includes a permeation preventing part 230. The permeation preventing part 230 disposed of the frame 220 (i.e., within a reference distance from the frame 220), and does not contact a structure laminated on the substrate 110 when the substrate 110 and the cap 200 are bonded to each other. The permeation preventing part 230 includes at least two stoppers 231 and 232. The permeation preventing part 230 includes a first stopper 231 and a second stopper 232. The first stopper 231 and the second stopper 232 protrudes in a bonding direction of the resonator from a groove part 210 of the cap 200. The first stopper 231 and the second stopper 232 have the same height as that of the frame 220.

The first stopper 231 is adjacent to the frame 220 as compared to the second stopper 232 and is disposed along an inner side of the frame 220 of the cap 200.

The second stopper 232 is disposed on the groove part 210 along a side of the first stopper 231 opposite the frame 220. The second stopper 232 may be formed to correspond to the bonding region of the substrate 110 and the cap 200. The second stopper 232 is coupled to the first stopper 231 to form a closed portion. In order for the second stopper 232 to be coupled to the first stopper 231 to form the closed portion, the second stopper 232 forms “C” shape as illustrated in FIG. 4A. In addition, in order to improve surface tension strength with the bonding agent 250, an inner surface of the closed portion may be provided with teeth having a saw shape, a wave shape, or the like, thereby increasing roughness. Additionally, a structure may be disposed on the closed portion, or the surface of the closed portion may be chemically treated to roughen the inner surface.

The first stopper 231 prevents the bonding agent 250 from permeating into the active region of the resonating part 135, and the second stopper 232 blocks any bonding agent 250 that permeated beyond the first stopper 231 from entering into the active region of the resonating part 135. Accordingly, the problem of the bonding agent 250 permeating into the active region of the resonating part 135 is prevented by disposing the first and second stoppers 231 and 232 in the proximity of the bonding region of the substrate 110 and the cap 200.

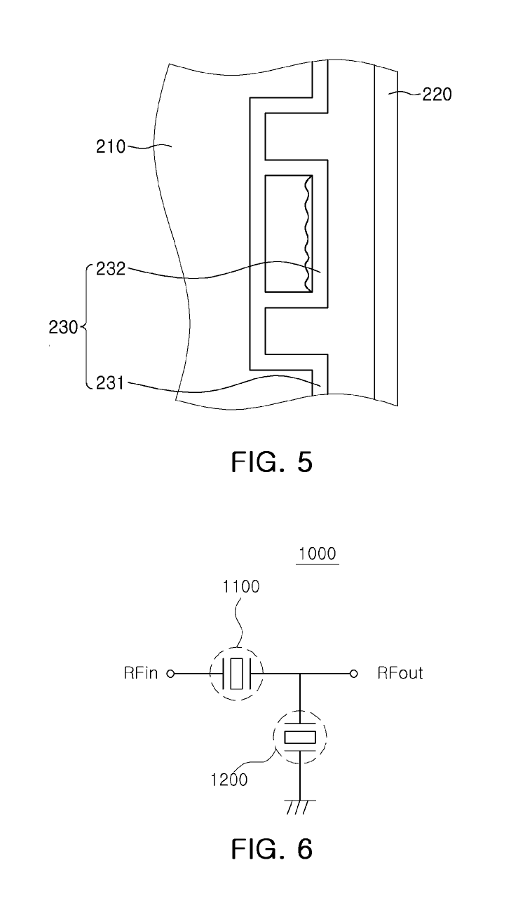

FIG. 5 is a modified embodiment of FIG. 4A. Referring to FIG. 5, the cap 200 includes the permeation preventing part 230. The permeation preventing part 230 includes at least two stoppers. Specifically, the permeation preventing part 230 includes a first stopper 231 and a second stopper 232.

The first stopper 231 and the second stopper 232 protrude in the bonding direction (i.e., a height direction of the frame) from the groove part 210 of the cap 200. The first stopper 231 and the second stopper 232 have the same height as that of the frame 220. The first stopper 231 is disposed adjacent to the frame 220 as compared to the second stopper 232, and has a quadrangular shape on an inner side of the frame 220. Here, the first stopper 231 protrudes to an opposite side of the frame 220 in the bonding region of the substrate 110 and the cap 200. The second stopper 232 is disposed between the first stopper 231 and the frame 220. The second stopper 232 corresponds to the bonding region of the substrate 110 and the cap 200.

The second stopper 232 is coupled to the first stopper 231 to form a closed portion. In order for the second stopper 232 to be coupled to the first stopper 231 to form the closed portion, the second stopper 232 has bent portion. For example, the second stopper 232 has “C” shape as illustrated in FIG. 5.

In addition, in order to improve surface tension strength with the bonding agent 250, an inner surface of the closed portion has teeth in a saw shape, or a wave shape, thereby increasing surface roughness. Additionally, a structure may be disposed on the closed portion, or the surface of the closed portion may be chemically treated to roughen the inner surface.

The boding agent is primarily blocked from permeating the active region of the resonating part 135 by the first stopper 231. The second stopper 232 serves as a secondary block, preventing any bonding agent 250 which permeated the first stopper 231 from reaching the active region of the resonating part 135.

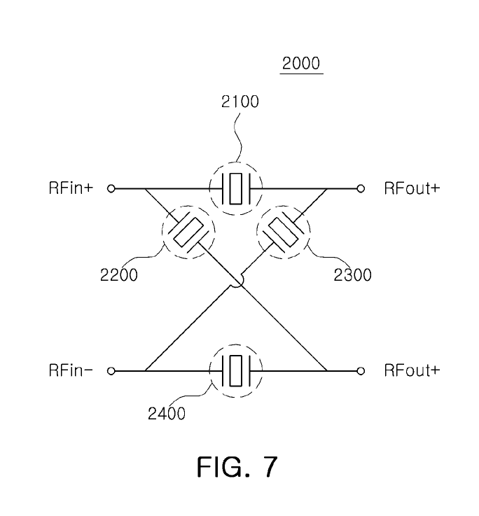

Referring to FIGS. 6 and 7, each of the bulk acoustic wave resonators 1100, 1200, 2100, 2200, 2300, and 2400 comprise the bulk acoustic wave resonator as illustrated in FIG. 1.

Referring to FIG. 6, a filter 1000 is a ladder type filter. Specifically, the filter 1000 includes a plurality of bulk acoustic wave resonators 1100 and 1200. A first bulk acoustic wave resonator 1100 is connected in series between a signal input terminal to which an input signal RFin is input and a signal output terminal from which an output signal RFout is output, and a second bulk acoustic wave resonator 1200 is connected between the signal output terminal and a ground.

Referring to FIG. 7, a filter 2000 is a lattice type filter. Specifically, the filter 2000 includes a plurality of bulk acoustic wave resonators 2100, 2200, 2300, and 2400 to filter balanced input signals RFin+and RFin- and output balanced output signals RFout+and RFout−.

As set forth above, the bonding agent permeated into the active region of the resonator is prevented, whereby reliability is increased.

As a non-exhaustive example only, a terminal/device/unit as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator comprising:
a resonating part comprising a first electrode, a piezoelectric layer, and a second electrode sequentially laminated, wherein the resonating part is disposed on a substrate; and
a cap comprising a groove part configured to accommodate the resonating part, a frame bonded to the substrate by a bonding agent, and a permeation preventing part configured to block the bonding agent from permeating into the groove part from the frame.

2. The bulk acoustic wave resonator of claim 1, wherein the permeation preventing part extends perpendicularly from the groove part.

3. The bulk acoustic wave resonator of claim 1, wherein the permeation preventing part has a same height as a height of the frame.

4. The bulk acoustic wave resonator of claim 1, wherein the permeation preventing part includes at least two stoppers extend from the groove part within a reference distance from the frame.

5. The bulk acoustic wave resonator of claim 4, wherein the at least two stoppers include a first stopper and a second stopper,
the first stopper is formed to be adjacent to the frame as compared to the second stopper, and
the second stopper is coupled to the first stopper to form a closed portion.

6. The bulk acoustic wave resonator of claim 5, wherein the first stopper extends along a length of the frame.

7. The bulk acoustic wave resonator of claim 5, wherein the second stopper has a C-shape.

8. The bulk acoustic wave resonator of claim 5, wherein the second stopper is disposed on one side of the first stopper and the frame is disposed on another side of the first stopper.

9. The bulk acoustic wave resonator of claim 5, wherein the second stopper is provided between the first stopper and the frame.

10. The bulk acoustic wave resonator of claim 5, wherein an inner surface of the closed portion comprises a saw-tooth shape or a wave shape.

11. The bulk acoustic wave resonator of claim 5, wherein a structure for increasing surface roughness is disposed on an inner surface of the closed portion.

12. A filter comprising:
bulk acoustic wave resonators, wherein each of the bulk acoustic wave resonators comprise:
a resonating part comprising a first electrode, a piezoelectric layer, and a second electrode sequentially laminated, wherein the resonating part is disposed on a substrate; and
a cap comprising a groove part configured to accommodate the resonating part, a frame bonded to the substrate by a bonding agent, and a permeation preventing part configured to block the bonding agent from permeating into the groove part from the frame.

13. The filter of claim 12, wherein the permeation preventing part comprises a first stopper and a second stopper extending from the groove part.

14. The filter of claim 13, wherein the second stopper comprises a closed portion comprising an inner surface, wherein the inner surface comprises a saw-tooth or wave shape.
